(19) United States
(12) Patent Application Publication
(10) Pub. No.: US 2024/0011187 A1
(43) Pub. Date: Jan. 11, 2024

(54) CRYSTAL GROWTH FURNACE SYSTEM

(71) Applicant: GlobalWafers Co., Ltd., Hsinchu (TW)

(72) Inventors: Ching-Shan Lin, Hsinchu (TW); Ye-Jun Wang, Hsinchu (TW); Chien-Cheng Liou, Hsinchu (TW)

(73) Assignee: GlobalWafers Co., Ltd., Hsinchu (TW)

(21) Appl. No.: 18/344,865

(22) Filed: Jun. 30, 2023

Related U.S. Application Data
(60) Provisional application No. 63/359,212, filed on Jul. 8, 2022.

(51) Int. Cl. C30B 23/06

(52) U.S. Cl. CPC C30B 23/06

(57) ABSTRACT

A crystal growth furnace system, including an external heating module, a furnace, a first driven device, a second driven device, and a control device, is provided. The furnace is movably disposed in the external heating module. The first driven device drives the furnace to move along an axis. The second driven device drives the furnace to rotate around the axis. The control device is electrically connected to the first driven device, the second driven device, and the external heating module.

### CROSS-REFERENCE TO RELATED APPLICATION

This application claims the priority benefit of U.S. provisional application Ser. No. 63/359,212, filed on Jul. 8, 2022. The entirety of the above-mentioned patent application is hereby incorporated by reference herein and made a part of this specification.

### BACKGROUND

### Technical Field

The disclosure relates to a crystal growth furnace system, and in particular to a crystal growth furnace system with a movable and rotatable furnace.

### Description of Related Art

The conventional crystal growth furnaces may be divided into the fixed type and the movable type. The difference is that the furnace and the external heating module of the fixed type crystal growth furnace are both fixed, while the external heating module of the movable type crystal growth furnace is movable. Generally speaking, the fixed type crystal growth furnace has the conventional issue of uneven heating of the furnace. The uneven heating of the furnace causes a large temperature difference between the front and rear end surfaces of the produced crystal, resulting in an increase in the stress difference between the front and rear end surfaces, which affects the thickness and the quality of the crystal.

Although the movable type crystal growth furnace can improve the issue of uneven heating by the movable external heating module, the lifting mechanism that controls the movement of the external heating module causes the electromagnetic induction of the external heating module to be uneven, which affects the effect of the improvement, and also causes the thickness and the quality of the crystal to be reduced.

### SUMMARY

The disclosure provides a crystal growth furnace system, which enables a furnace to be evenly heated by a movable or/and rotatable furnace, so as to reduce the temperature difference and the stress difference at two ends of a crystal, thereby increasing the thickness and improving the quality of the crystal.

A crystal growth furnace system of the disclosure includes an external heating module, a furnace, a first driven device, a second driven device, and a control device. The furnace is movably disposed in the external heating module. The first driven device drives the furnace to move along an axis. The second driven device drives the furnace to rotate around the axis. The control device is electrically connected to the first driven device, the second driven device, and the external heating module.

In an embodiment of the disclosure, the control device controls the first driven device and the second driven device to simultaneously or not simultaneously operate, so that the furnace moves or/and rotates in the external heating module.

In an embodiment of the disclosure, the first driven device drives the furnace to move along the axis with a maximum moving distance of less than or equal to 200 mm.

In an embodiment of the disclosure, the first driven device drives the furnace to move along the axis with a minimum movable distance of greater than or equal to 0.1 m.

In an embodiment of the disclosure, the first driven device drives the furnace to move along the axis with a speed of between 0.05 mm/hour and 100 mm/minute.

In an embodiment of the disclosure, the second driven device drives the furnace to rotate around the axis with a maximum rotating speed of less than 20 rpm.

In an embodiment of the disclosure, the external heating module is a heating coil group, and the heating coil group covers a moving range of the furnace moving along the axis.

In an embodiment of the disclosure, the crystal growth furnace system further includes a heat insulating layer covering the furnace and linked to the furnace.

In an embodiment of the disclosure, the crystal growth furnace system further includes a weighing scale located below the furnace to measure a weight of the furnace.

In an embodiment of the disclosure, the furnace is filled with a raw material and a seed crystal is provided on an inner top wall of the furnace.

Based on the above, the crystal growth furnace system of the disclosure includes the furnace movably disposed in the external heating module, and the furnace is moved or/and rotated by the first driven device and the second driven device. Such a design can enable the furnace to be evenly heated, so that the crystal can be evenly heated, so as to obtain a thicker crystal with improved quality.

### BRIEF DESCRIPTION OF THE DRAWINGS

FIG. 1 is a schematic diagram of a crystal growth furnace system according to an embodiment of the disclosure.

FIG. 2 is a schematic diagram of a crystal formed according to an embodiment of the disclosure.

FIG. 3 is a schematic diagram of a relationship between a temperature of an end surface and a crystal radial position of the crystal of FIG. 2 at multiple time points.

FIG. 4A is a schematic diagram of a relationship between a temperature of an end surface and a crystal radial position of a crystal formed in a conventional fixed type crystal growth furnace at multiple time points.

FIG. 4B is a schematic diagram of a relationship between a temperature of an end surface and a crystal radial position of a crystal formed in a conventional movable type crystal growth furnace at multiple time points.

FIG. 5 is an ingot of the crystal of FIG. 2 after spheronization.

FIG. 6 is a wafer of the ingot of FIG. 5 after cutting, grinding, and polishing.

### DESCRIPTION OF THE EMBODIMENTS

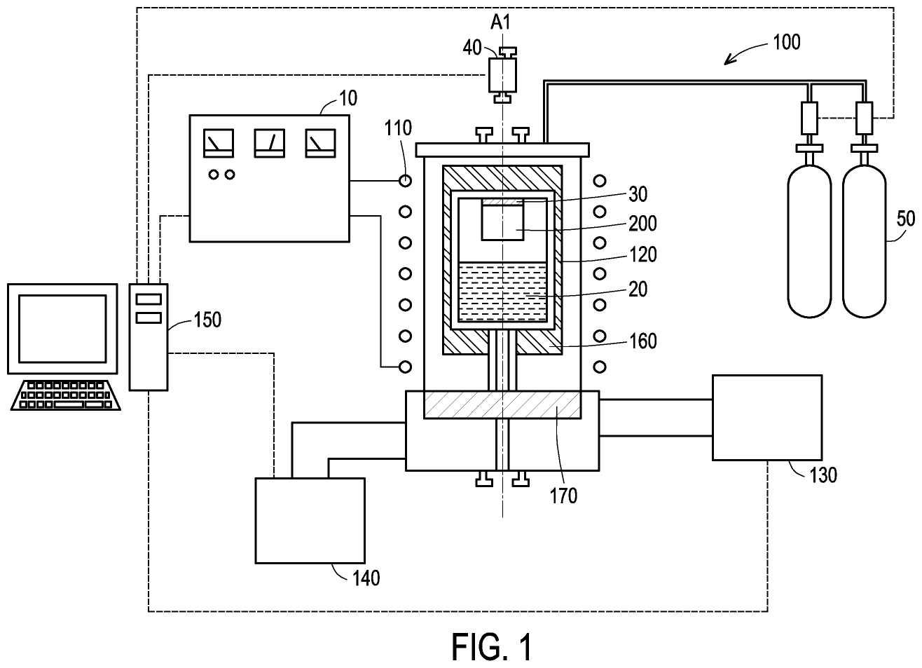

FIG. 1 is a schematic diagram of a crystal growth furnace system according to an embodiment of the disclosure. Please refer to FIG. 1. A crystal growth furnace system 100 includes an external heating module 110, a furnace 120, a first driven device 130, a second driven device 140, and a control device 150. The external heating module 110 is electrically connected to a power supply 10. The furnace 120 is movably disposed in the external heating module 110 and is connected to a gas cylinder 50 with a gas pipe. The first driven device 130 drives the furnace 120 to move along an axis A1. The second driven device 140 drives the furnace 120 to rotate around the axis A1. The control device 150 is electrically connected to the first driven device 130, the second driven device 140, the external heating module 110, the power supply 10, and a thermometer 40.

The control device 150 controls the first driven device 130 and the second driven device 140 to simultaneously or not simultaneously operate, so that the furnace 120 moves or/and rotates in the external heating module 110. For example, the furnace 120 may first move up and down, then rotate at the same height, and finally simultaneously rotate during the process of moving up and down.

Therefore, compared with an external heating module of a conventional movable type crystal growth furnace, which can only move up and down relative to a furnace, the furnace 120 of the crystal growth furnace system 100 of the disclosure may not only move up and down relative to the external heating module 110, but also rotate relative to the external heating module 110, and the crystal growth furnace system 100 may control the movement and the rotation to simultaneously or not simultaneously operate. Such a design can enable the furnace 120 be more evenly heated, so that the crystal 200 can be more evenly heated, so as to obtain the thicker crystal 200 with improved quality.

In addition, in the embodiment, the external heating module 110 is a heating coil group, and the heating coil group covers a moving range of the furnace 120 moving along the axis A1.

On the other hand, in the embodiment, the first driven device 130 drives the furnace 120 to move along the axis A1 with a maximum moving distance of less than or equal to 200 mm, a minimum movable distance of greater than or equal to 0.1 μm, and a moving speed of between 0.05 mm/hour and 100 mm/minute. In addition, the second driven device 140 drives the furnace 120 to rotate around the axis A1 with a maximum rotating speed of less than 20 rpm and a minimum adjustable rotating speed of greater than or equal to 0.01 rpm.

As shown in FIG. 1, the crystal growth furnace system 100 further includes a heat insulating layer 160 covering the furnace 120 and linked to the furnace 120 to maintain the temperature of the furnace 120, so as to prevent the temperature difference of the furnace 120 from being too large. On the other hand, the crystal growth furnace system 100 further includes a weighing scale 170 located below the furnace 120 to weigh the total weight of the furnace 120, the heat insulating layer 160, the crystal 200, and a silicon carbide raw material 20. Such a design can detect the weight loss of the vaporized silicon carbide raw material 20 being pumped. In the embodiment, the maximum load that the weighing scale 170 may withstand is greater than or equal to 3 kg, such as 5 kg or 10 kg, and the minimum weight loss rate resolvable by the weighing scale 170 is greater than or equal to 0.1 g/hour.

Please refer to FIG. 1 again. When using the crystal growth furnace system 100 to implement a crystal growth method for forming the crystal 200, the furnace 120 of the crystal growth furnace system 100 is filled with the silicon carbide raw material 20 and a seed crystal 30 is provided on an inner top wall of the furnace 120. After a certain period of time, the crystal 200 may be formed below the seed crystal 30.

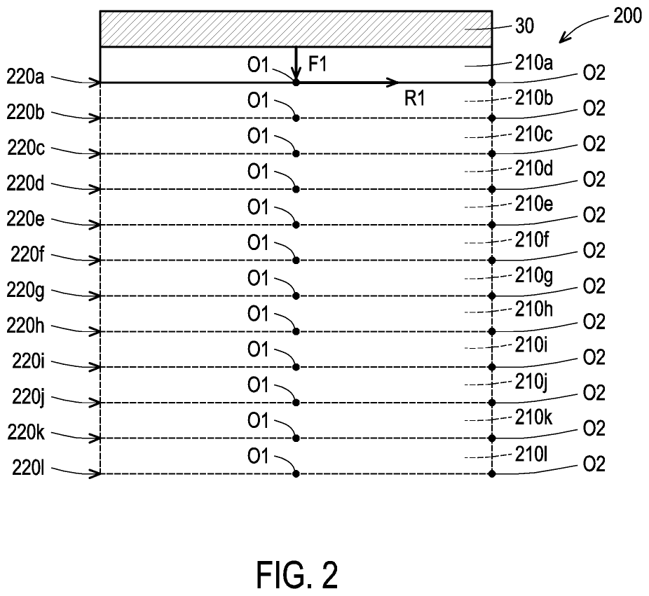

FIG. 2 is a schematic diagram of a crystal formed according to an embodiment of the disclosure. Please refer to FIG. 2. The seed crystal 30 forms the crystal 200 along a first direction F1 after multiple time points. The crystal 200 includes multiple sub-crystals 210a to 210l stacked along the first direction F1. The corresponding sub-crystal 210a to 210l is formed at each of the time points. In the embodiment, the number of the sub-crystals 210a to 210l is 12, and the interval between the time points is 10 hours, but the number and the interval are not limited thereto. The number of sub-crystals may be 20, and the time interval may be 10 hours. In other embodiments, the number of sub-crystals may be 10, and the time interval may be 5 hours, which may be adjusted according to the manufacturing design, and the disclosure is not limited thereto. The sub-crystals 210a to 210l include multiple end surfaces 220a to 220l away from the seed crystal 30. Specifically, the end surfaces 220a to 220l are interfaces between solid, that is, the crystal 200 and gas during a sublimation process. A center O1 of each of the end surfaces 220a to 220l is respectively located at an intersection of the first direction F1 corresponding to the end surfaces 220a to 220l. It should be noted that FIG. 2 is only one of the embodiments. In other embodiments, the sizes of the sub-crystals 210a to 210l from the centers O1 to maximum crystal radial positions O2 may be the same or different, and the disclosure is not limited thereto.

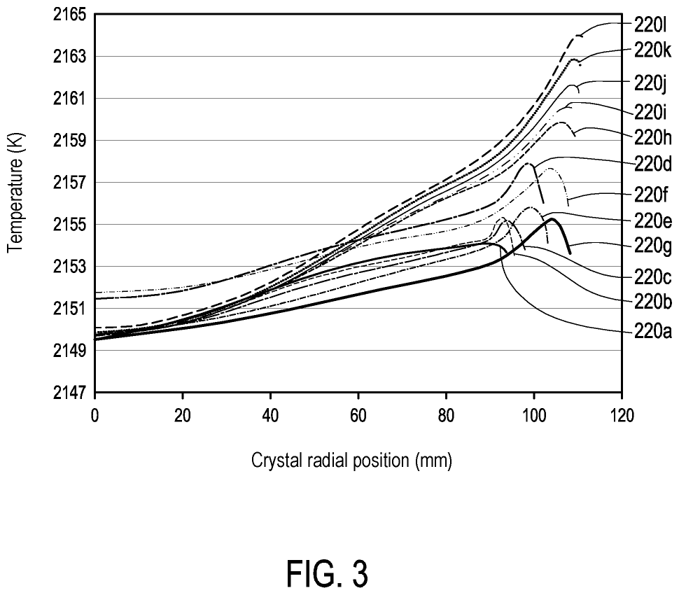

FIG. 3 is a schematic diagram of a relationship between a temperature of an end surface and a crystal radial position of the crystal 200 of FIG. 2 at multiple time points. As shown in FIG. 3, each line represents the sub-crystals 210a to 210l stacked along the first direction F1 and the temperature measured on each of the end surfaces 220a to 220l of the sub-crystals 210a to 210l, wherein the crystal radial position 0 mm on the horizontal axis represents the center O1 of each of the end surfaces 220a to 220l, and the remaining crystal radial positions are distances from the centers O1 of the end surfaces 220a to 220l along a radial direction R1 relative to the centers O1. It is worth noting that the process of the seed crystal 30 forming the crystal 200 after the time points may include growing along the first direction F1 and along the radial direction R1, and the disclosure is not limited thereto.

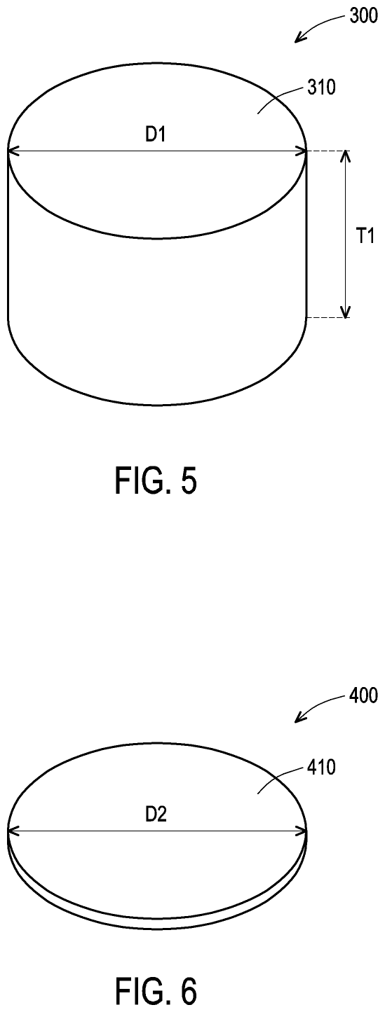

In the temperature curves of the end surfaces 220a to 220l, when comparing own temperature differences of the end surfaces 220a to 220l, that is, from the centers O1 to the maximum crystal radial positions O2 of the end surfaces 220a to 220l, the end surface 220a has the smallest temperature difference, and the temperature difference is about 3 to 5 degrees. The end surface 220l has the largest temperature difference, and the temperature difference is about 10 to 15 degrees. On the other hand, when comparing the temperature differences of the end surfaces 220a to 220l at the same crystal radial positions, the centers O1 of the end surfaces 220a to 220l has smaller temperature differences, and the temperature differences are about 0 to 3 degrees. The maximum crystal radial positions O2 of the end surfaces 220a to 220l has larger temperature differences, and the temperature differences are about 10 to 20 degrees. In other words, among the end surfaces 220a to 220l, regardless of whether at the same radii or at different radii, the difference value between the temperatures of any two is about 20 degrees or less, such as 15 degrees, 10 degrees, 5 degrees, or 2 degrees. In other words, regardless of to which of the sub-crystals 210a to 210l the crystal 200 is stacked along the first direction F1, when measuring any position at any time, and the difference value between the temperatures of any two is about 20 degrees or less. During the growth process of the crystal 200 of the embodiment, the high-quality, large-size, and large-thickness crystal 200 and wafer 400 (FIG. 6) with low stress are grown by reducing the temperature gradient variation of a thermal field.

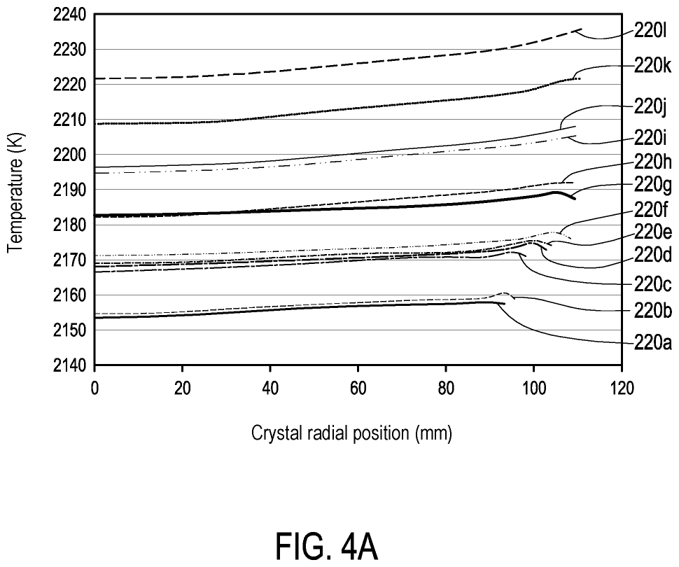

FIG. 4A is a schematic diagram of a relationship between a temperature of an end surface and a crystal radial position of a crystal formed in a conventional fixed type crystal growth furnace at multiple time points. Please refer to FIG. 4A. In the temperature curves of the end surfaces 220a to 220l, when comparing the own temperature differences of the end surfaces 220a to 220l, the end surface 220a has the smallest temperature difference, and the temperature difference is about 5 degrees. The end surface 220l has the largest temperature difference, and the temperature difference is about 15 degrees. On the other hand, when comparing the temperature differences of the end surfaces 220a to 220l at the same crystal radial positions, the temperature differences of the centers of the end surfaces 220a to 220l are at most about 70 degrees, and the maximum temperature difference of the maximum crystal radial positions O2 of the end surfaces 220a to 220l is about 80 degrees.

FIG. 4B is a schematic diagram of a relationship between a temperature of an end surface and a crystal radial position of a crystal formed in a conventional movable type crystal growth furnace at multiple time points. Please refer to FIG. 4B. In the temperature curves of the end surfaces 220a to 220l, when comparing the own temperature differences of the end surfaces 220a to 220l, the end surface 220a has the smallest temperature difference, and the temperature difference is about 5 degrees. The end surface 220l has the largest temperature difference, and the temperature difference is about 15 degrees. On the other hand, when comparing the temperature differences of the end surfaces 220a to 220l at the same crystal radial positions, the temperature differences of the centers of the end surfaces 220a to 220l are at most about 12 degrees, and the maximum temperature difference of the maximum crystal radial positions O2 of the end surfaces 220a to 220l is about greater than 20 degrees.

From the results of FIG. 3, FIG. 4A, and FIG. 4B, it can be known that when the crystal growth method for forming the crystal 200 is implemented by the crystal growth furnace system 100, the own temperature differences of the end surfaces 220a to 220l and the temperature differences between the end surfaces 220a to 220l of the crystal 200 are significantly reduced. As a result, the stress difference between the crystals 200 is reduced, thereby increasing the thickness T1 and the size and improving the quality of the crystal 200.

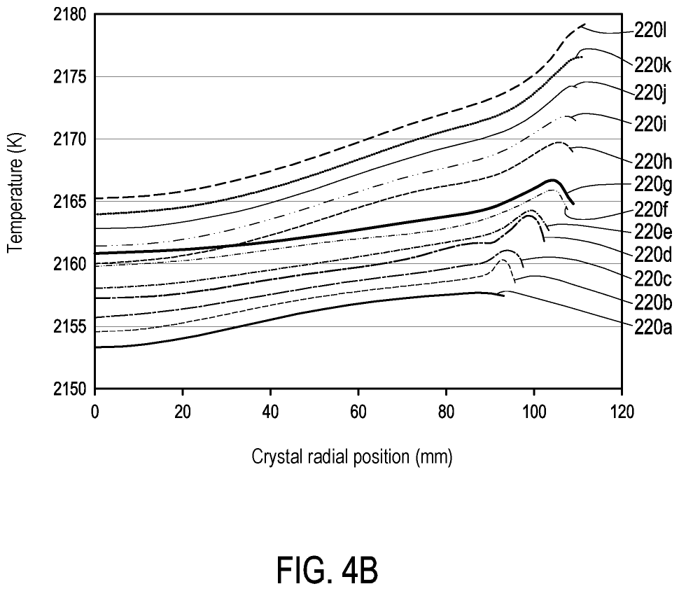

FIG. 5 is an ingot of the crystal of FIG. 2 after spheronization. An ingot 300 shown in FIG. 5 is a finished product of the crystal 200 formed by the crystal growth method and after spheronization, and the ingot 300 has the advantages of the preferable thickness and quality of the crystal 200. Therefore, a diameter D1 of an ingot body 310 of the ingot 300 is greater than or equal to 150 mm, and a thickness T1 is greater than or equal to 15 mm. For example, the diameter D1 is 150 mm, and the thickness T1 is greater than or equal to 25 mm, or the diameter D1 is 200 mm, and the thickness T1 is greater than or equal to 15 mm.

FIG. 6 is a wafer of the ingot of FIG. 5 after cutting, grinding, and polishing. A diameter D2 of the wafer 400 shown in FIG. 6 is close to the diameter D1 of the ingot 300 shown in FIG. 5. Therefore, the diameter D2 of a wafer body 410 of the wafer 400 is greater than or equal to 150 mm or greater than or equal to 200 mm.

In addition, the wafer 400 after cutting, grinding, and polishing also has the preferable quality of the ingot 300. Therefore, a basal plane dislocation (BPD) of the wafer body 410 is less than or equal to 1000 ea/cm², and a bar stacking fault of the wafer body 410 is less than or equal to 100 ea/wf. The BPD is, for example, less than or equal to 500 ea/cm², 300 ea/cm², or 200 ea/cm². The bar stacking fault is, for example, less than or equal to 50 ea/wf, 30 ea/wf, or 10 ea/wf.

On the other hand, a bow of the wafer body 410 is between plus or minus 15 μm, plus or minus 30 μm, or plus or minus 50 μm. A warp of the wafer body 410 is less than or equal to 50 μm, less than or equal to 30 μm, or less than or equal to 10 μm.

In summary, the crystal growth furnace system of the disclosure drives the furnace to move or/and rotate in the external heating module by the first driven device and the second driven device, so that the furnace can be evenly heated. Such a design can enable the temperature difference at different positions of the produced crystal to be reduced, thereby also reducing the stress difference between different positions of the crystal, so that the overall thickness of the crystal can be increased, and the quality can be improved.

What is claimed is:

1. A crystal growth furnace system, comprising:
an external heating module;
a furnace, movably disposed in the external heating module;
a first driven device, driving the furnace to move along an axis;
a second driven device, driving the furnace to rotate around the axis; and
a control device, electrically connected to the first driven device, the second driven device, and the external heating module.

2. The crystal growth furnace system according to claim 1, wherein the control device controls the first driven device and the second driven device to simultaneously or not simultaneously operate, so that the furnace moves or/and rotates in the external heating module.

3. The crystal growth furnace system according to claim 1, wherein the first driven device drives the furnace to move along the axis with a maximum moving distance of less than or equal to 200 mm.

4. The crystal growth furnace system according to claim 1, wherein the first driven device drives the furnace to move along the axis with a minimum movable distance of greater than or equal to 0.1 μm.

5. The crystal growth furnace system according to claim 1, wherein the first driven device drives the furnace to move along the axis with a speed of between 0.05 mm/hour and 100 mm/minute.

6. The crystal growth furnace system according to claim 1, wherein the second driven device drives the furnace to rotate around the axis with a maximum rotating speed of less than 20 rpm.

7. The crystal growth furnace system according to claim 1, wherein the external heating module is a heating coil group, and the heating coil group covers a moving range of the furnace moving along the axis.

8. The crystal growth furnace system according to claim 1, further comprising a heat insulating layer covering the furnace and linked to the furnace.

9. The crystal growth furnace system according to claim 1, further comprising a weighing scale located below the furnace to measure a weight of the furnace.

10. The crystal growth furnace system according to claim 1, wherein the furnace is filled with a raw material and a seed crystal is provided on an inner top wall of the furnace.
